(19) United States
(12) Patent Application Publication
(10) Pub. No.: US 2019/0113555 A1
(43) Pub. Date: Apr. 18, 2019

(54) ELECTROMAGNETIC FIELD PROBE

(71) Applicant: Mitsubishi Electric Corporation, Tokyo (JP)

(72) Inventors: Ryota KOBAYASHI, Tokyo (JP); Tsuyoshi KOBAYASHI, Tokyo (JP); Chiharu MIYAZAKI, Tokyo (JP)

(73) Assignee: Mitsubishi Electric Corporation, Tokyo (JP)

(21) Appl. No.: 16/087,160

(22) PCT Filed: Jun. 7, 2016
(86) PCT No.: PCT/JP2016/066902

§ 371 Date: Sep. 21, 2018

(51) Int. Cl. G01R 29/08; G01R 33/02; H01Q 21/06; H01Q 21/24; H01Q 7/00

(52) U.S. Cl. CPC G01R 29/0878; G01R 33/02; H01Q 7/00; H01Q 21/24; H01Q 21/061

(57) ABSTRACT

Two linear conductors are orthogonally arranged to each other without short-circuiting. Both ends of one of the linear conductors are connected to corresponding both ends of another of the linear conductors by connecting conductors to form a continuous loop. A pair of terminals is provided in one divided portion in the loop. Loop antennas each including the linear conductors, the connecting conductors, and the terminals are linearly arranged, and the loop antennas adjacent to each other are arranged to be rotated relative to each other on a plane.

### TECHNICAL FIELD

The present invention relates to an electromagnetic field probe using a loop antenna.

### BACKGROUND ART

One method commonly used as a detection method of an electromagnetic field probe is a loop antenna. A conventional loop antenna has a loop structure formed on a plane, and by being arranged so that a magnetic field generated from a measurement target passes through a loop plane, an induced current is generated in the loop. As a result, a current flowing through the measurement target can be detected.

Conventionally, as such a loop antenna, there has been one in which linear conductors orthogonally arranged to each other, both ends of these linear conductors are connected to each other, and a continuous loop is formed on the same plane (see, for example, Non-Patent Literature 1).

### CITATION LIST

### Non-Patent Literature

Non-Patent Literature 1: Tsuyoshi Kobayashi, et al., “A Study of magnetic probe for signal trace on PCB”, Proceedings of the Society Conference of the Institute of Electronics, Information and Communication Engineers, Environmental Electromagnetic Compatibility (B-4) General Session, B-4-18, 2015.

### SUMMARY OF INVENTION

### Technical Problem

However, with the above-described conventional technique, although the antenna structure in which the loop is twisted can detect the current without changing the orientation with respect to wiring lines routed in various directions; there is a problem that, depending on conditions such as a position and a direction of a wiring line, the current cannot be detected because the magnetic flux is canceled out in two loops continuously formed, or one loop.

The present invention has been made to solve such a problem, and it is an object to provide an electromagnetic field probe capable of detecting a current occurring in a wiring line without changing its orientation even for wiring lines routed in various directions.

### Solution to Problem

An electromagnetic field probe according to the present invention includes a plurality of loop antennas on an identical plane, the loop antennas each including: two linear conductors orthogonally arranged to each other without short-circuiting; two connecting conductors connecting both ends of one of the two linear conductors to corresponding both ends of another of the two linear conductors to form a continuous loop; and a pair of terminals provided at one divided portion in the loop, in which the plurality of loop antennas is linearly arranged, and the loop antennas adjacent to each other are arranged to be rotated relative to each other on the plane.

### Advantageous Effects of Invention

In the electromagnetic field probe according to the present invention, a plurality of loop antennas is linearly arranged, and the loop antennas adjacent to each other are arranged to be rotated relative to each other. As a result, a current generated in a wiring line can be detected without changing the orientation of the electromagnetic field probe with respect to wiring lines routed in various directions.

### BRIEF DESCRIPTION OF DRAWINGS

FIG. 1 is a configuration diagram illustrating an electromagnetic field probe of a first embodiment of the present invention.

FIG. 2 is a configuration diagram illustrating another example of the electromagnetic field probe in the first embodiment of the present invention.

FIG. 3 is an explanatory diagram illustrating detection operation of the electromagnetic field probe in the first embodiment of the present invention.

FIGS. 4A and 4B are explanatory diagrams illustrating detection operation of a wiring line at another angle of the electromagnetic field probe in the first embodiment of the present invention.

FIG. 5 is a configuration diagram illustrating an electromagnetic field probe in a second embodiment of the present invention.

FIG. 6 is a configuration diagram illustrating another example of the electromagnetic field probe in the second embodiment of the present invention.

FIG. 7 is a configuration diagram illustrating yet another example of the electromagnetic field probe in the second embodiment of the present invention.

FIG. 8 is an explanatory diagram illustrating detection operation of the electromagnetic field probe in the second embodiment of the present invention.

FIG. 9 is an explanatory diagram illustrating detection operation of a wiring line at another position of the electromagnetic field probe in the second embodiment of the present invention.

### DESCRIPTION OF EMBODIMENTS

Hereinafter, in order to explain the present invention in more detail, embodiments for carrying out the present invention will be described with reference to the accompanying drawings.

### First Embodiment

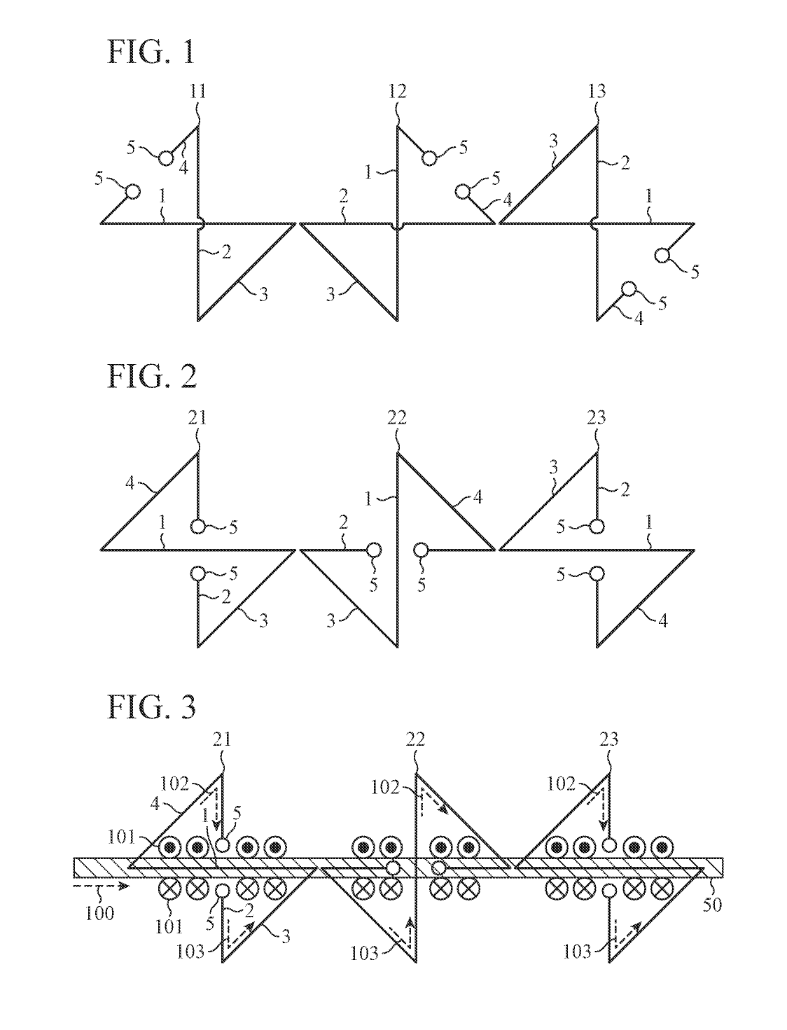

FIG. 1 is a configuration diagram of an electromagnetic field probe according to the present embodiment.

As illustrated in FIG. 1, the electromagnetic field probe according to the present embodiment includes a plurality of loop antennas 11, 12, and 13. In each of the loop antennas 11, 12, and 13, linear conductors 1 and 2 are orthogonally arranged to each other without short-circuiting. In the example of the figure, the linear conductors 1 and 2 are of equal length and intersect at the midpoint. In addition, both ends of the linear conductors 1 and 2 are connected to each other by connecting conductors 3 and 4. As a result, a continuous loop is formed by the linear conductors 1 and 2 and the connecting conductors 3 and 4. Further, the continuous loop is divided at one place, and a pair of terminals 5 is provided in the divided portion. The pair of terminals 5 is for drawing out a detection current generated in the loop. In the example of FIG. 1, the connecting conductor 4 is divided at the midpoint and the pair of terminals 5 is provided there.

Here, the electromagnetic field probe illustrated in FIG. 1 is arranged so that the loop antennas 11, 12, and 13 are linearly arranged, and the loop antennas 11, 12, and 13 adjacent to each other are rotated relative to each other by 90 degrees. That is, the loop antenna 12 has an arrangement in which the loop antenna 11 is rotated clockwise by 90 degrees, and the loop antenna 13 has an arrangement in which the loop antenna 12 is rotated clockwise by 90 degrees.

Note that, in the illustrated example, three loop antennas 11, 12, and 13 are arranged; however, the number of loop antennas is not limited to three. In addition, the fact that the linear conductor 1 and the linear conductor 2 are orthogonal to each other means that the linear conductor 1 and the linear conductor 2 may be substantially orthogonal at an angle within a range that does not affect detection characteristics as the electromagnetic field probe, and a certain allowable range is included. Further, the angle at which each of the loop antennas 11, 12, and 13 is rotated is not limited to 90 degrees, and another angle is also applicable.

Here, in the electromagnetic field probe illustrated in FIG. 1, since the linear conductor 1 and the linear conductor 2 intersect each other three-dimensionally, the linear conductor 1 and the linear conductor 2 cannot be formed on a single plane. On the other hand, as illustrated in FIG. 2, for example, one of the linear conductors 1 and 2 is divided at the intersecting position and the pair of terminals 5 is provided and linearly arranged, whereby loop antennas 21, 22, and 23 can be formed on a single plane. In the illustrated example, the linear conductor 2 that is one linear conductor is divided and the terminals 5 are provided, and the linear conductor 1 that is the other linear conductor is formed into a continuous shape.

Next, current detection of the electromagnetic field probe formed as described above will be described with reference to FIG. 3. Here, a principle of detecting a current using the electromagnetic field probe illustrated in FIG. 2, occurring on a wiring line 50 through which power feeding or signal transmission is performed will be described. Here, when a printed circuit board wiring line is a measurement target, most of wiring line directions are 0 degrees and 90 degrees, which are orthogonal. In addition, a wiring line of 45 degrees or 135 degrees may be used in some cases.

First, a case will be described where the linear conductors 1 of the loop antennas 21 and 23 are positioned with respect to the wiring line 50 as illustrated in FIG. 3.

When a current 100 in the direction illustrated flows through the wiring line 50, clockwise magnetic flux 101 is generated around the wiring line 50 in accordance with the right-handed screw rule. At this time, the magnetic flux 101 passes through the upper left loops of the loop antennas 21 and 23 and the upper right loop of the loop antenna 22 to the upward direction from the downward direction, and the magnetic flux 101 passes through the lower right loops (the lower left loop in the loop antenna 22) to the downward direction from the upward direction on the page. In addition, since the loop antennas 21, 22, and 23 each are formed in a shape in which one side of the loop is twisted by 180 degrees, an induced current 102 generated in the upper left loops of the loop antennas 21 and 23 and an induced current 103 generated in the lower right loops are synthesized, and the induced current 102 generated in the upper right loop of the loop antenna 22 and the induced current 103 generated in the lower left loop are synthesized in a way in which the induced currents 102 and 103 intensify each other. As a result, in the case of the electromagnetic field probe illustrated in FIG. 3, the current flowing through the wiring line 50 can be detected.

Note that, when the wiring line 50 rotated clockwise by 90 degrees is arranged to be positioned on the linear conductor 2 of the loop antenna 21 illustrated in FIG. 3, the electromagnetic field probe can detect the current flowing through the wiring line 50 on the same principle.

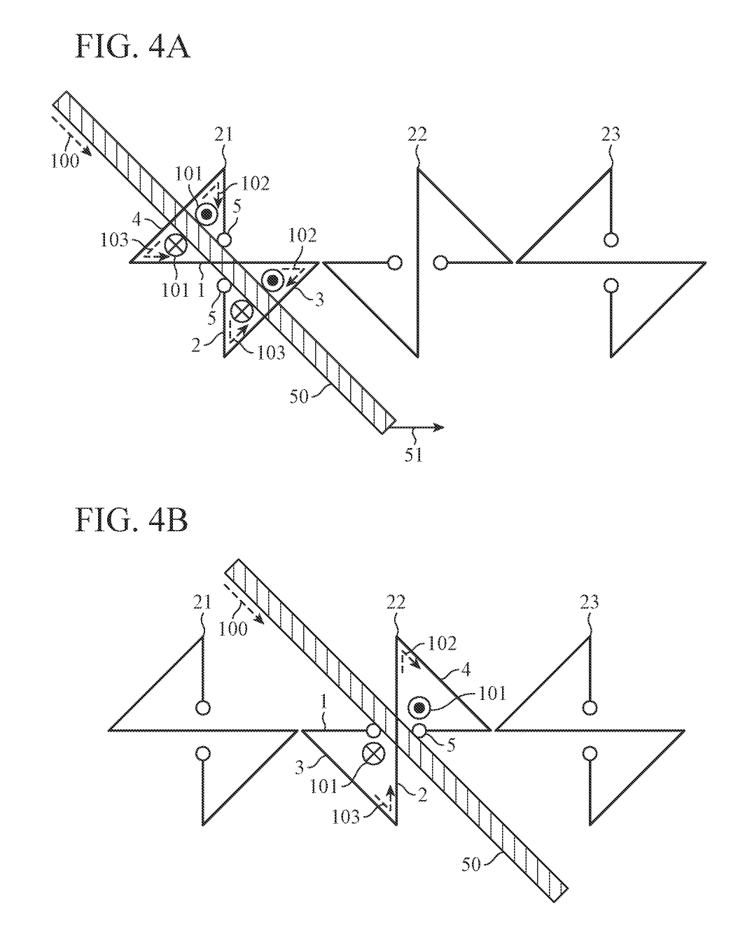

Next, with reference to FIG. 4A, a case is considered where the center of the loop antenna 21 is arranged on the wiring line 50 with respect to the wiring line 50 rotated clockwise by 45 degrees.

Also in this case, when the current 100 in the direction illustrated flows through the wiring line 50, the clockwise magnetic flux 101 is generated around the wiring line 50 in accordance with the right-handed screw rule. At this time, the upward magnetic flux 101 and the downward magnetic flux 101 equally pass through each of the upper left loop and the lower right loop of the loop antenna 21 with the wiring line 50 as the boundary. Therefore, the upward magnetic flux 101 and the downward magnetic flux 101 cancel each other out in the loop, and the induced currents 102 and 103 also cancel each other out. As a result, in a state illustrated in FIG. 4A, the current flowing through the wiring line 50 cannot be detected.

Next, a case will be described where the wiring line 50 is moved from the position of FIG. 4A to the direction of an arrow 51 as illustrated in FIG. 4B. A case is considered where the center of the loop antenna 22 positioned at the center is arranged to be positioned on the wiring line 50 with respect to the wiring line 50 rotated by 45 degrees illustrated in the figure.

Also in this case, when the current 100 in the direction illustrated flows through the wiring line 50, the clockwise magnetic flux 101 is generated around the wiring line 50 in accordance with the right-handed screw rule. At this time, the upward magnetic flux 101 and the downward magnetic flux 101 equally pass through the upper right loop and the lower left loop of the loop antenna 22, respectively, with the wiring line 50 as the boundary. In the upper right loop, the magnetic flux 101 passes to the upward direction from the downward direction on the page. In addition, the induced current 102 generated in the upper right loop and the induced current 103 generated in the lower left loop of the loop antenna 22 are synthesized in a way in which the induced currents 102 and 103 intensify each other. As a result, in the case of the electromagnetic field probe illustrated in FIG. 4B, the current flowing through the wiring line 50 can be detected.

Note that, when the wiring line 50 rotated clockwise by 135 degrees is moved in the direction of the arrow 51 as illustrated in FIGS. 4A and 4B, in a case where the center of each of the loop antennas 21, 22, and 23 is arranged to be positioned on the wiring line 50, the current flowing through the wiring line 50 can be detected by any one of the loop antennas 21, 22, and 23 without changing the orientation, on the same principle.

As described above, according to the electromagnetic field probe of the first embodiment, a plurality of loop antennas is included on an identical plane, the loop antennas each including: two linear conductors orthogonally arranged to each other without short-circuiting; two connecting conductors connecting both ends of the two linear conductors to each other to form a continuous loop; and a pair of terminals provided at one divided portion in the loop, wherein the plurality of loop antennas is linearly arranged, and the loop antennas adjacent to each other are arranged to be rotated relative to each other on the plane, so that a current generated in a wiring line can be detected without changing the orientation of the electromagnetic field probe with respect to wiring lines routed in various directions. In addition, compared with a single probe, multiple outputs can be obtained by one measurement, so that measurement time can be shortened.

Further, according to the electromagnetic field probe of the first embodiment, in the plurality of loop antennas, the loop antennas adjacent to each other are rotated relative to each other by 90 degrees, so that the current flowing through the wiring line can be detected without changing the orientation of the electromagnetic field probe, also for the wiring lines of 45 degrees and 135 degrees.

In addition, according to the electromagnetic field probe of the first embodiment, the divided portion is provided at an orthogonally intersecting portion of one of the two linear conductors, so that the electromagnetic field probe can be formed on a single plane.

### Second Embodiment

In a second embodiment, a plurality of loop antennas is provided, and the loop antennas are arranged in an array on a two-dimensional plane.

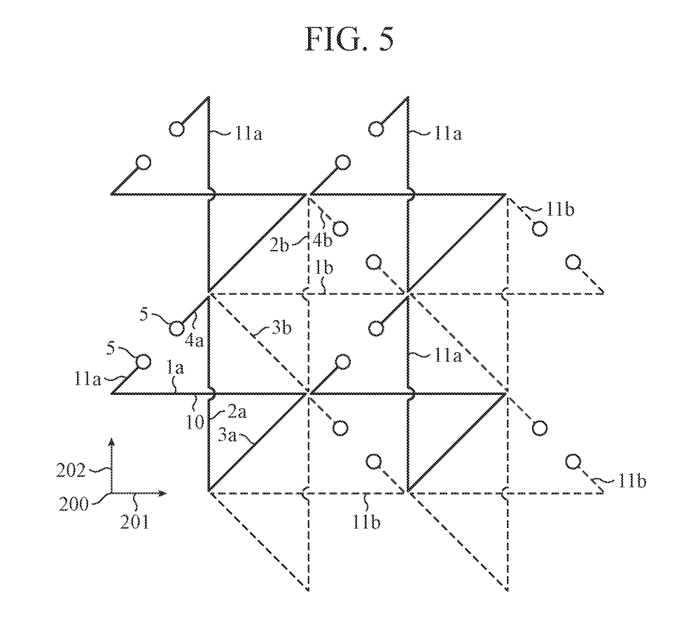

FIG. 5 is a configuration diagram illustrating an electromagnetic field probe in the second embodiment.

In the electromagnetic field probe illustrated in FIG. 5, a plurality of completely identical loop antennas (loop antennas 11a) drawn by solid lines is evenly arranged on a two-dimensional plane, the loop antennas each being at a position of nL in both an X axis 201 and a Y axis 202 from a reference point 200. Here, the reference point 200 is a point at the lower left corner of a rectangle circumscribing the loop antenna 11a at the lower left corner in FIG. 5. In addition, n is an integer, and the length of L is set to a value greater than the length of a linear conductor 1a of the loop antenna 11a so that the linear conductor 1a is not short-circuited with the conductor of the adjacent loop antenna. Further, the loop antenna (loop antenna 11b) indicated by a broken line is obtained by inverting the left and right of the loop antenna (loop antenna 11a) indicated by a solid line, and the loop antennas 11b are evenly arranged each being at a position of nL+L/2 in both the X axis 201 and the Y axis 202 from the reference point 200. Note that, in the loop antenna 11a, the linear conductors are denoted by 1a and 2a, and the connecting conductors are denoted by 3a and 4a. In addition, in the loop antenna 11b, the linear conductors are denoted by 1b and 2b, and the connecting conductors are denoted by 3b and 4b.

As a result, the inverted loop antennas can be evenly arranged at high density, the loop antennas each being at a position of nL in both the X axis 201 and the Y axis 202 from the reference point 200, and as illustrated, the connecting conductor 3a (3b) and 4b (4a) are not in parallel to each other, an interference amount is reduced between adjacent loop antennas, and the current detection of a target wiring line 50 is not prevented. However, although totally eight loop antennas are arranged in FIG. 5, this is not a limitation, and any number of loop antennas may be arranged.

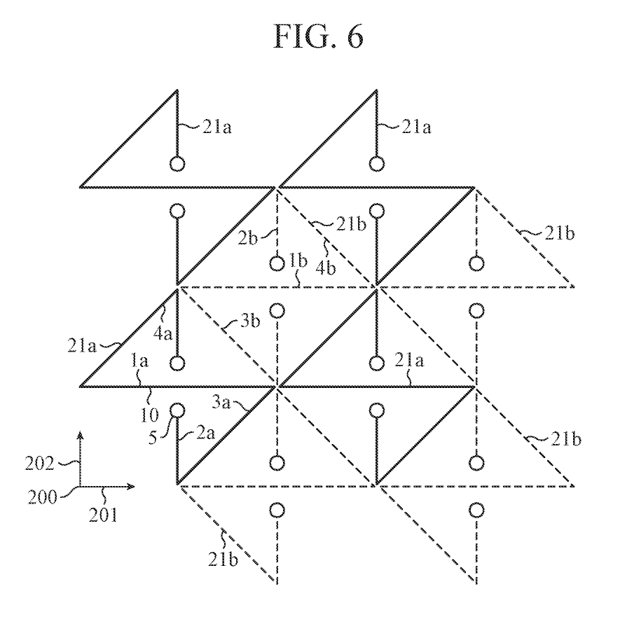

Here, in the electromagnetic field probe illustrated in FIG. 5, since the linear conductor 1a (1b) and the linear conductor 2a (2b) three-dimensionally intersect each other, the linear conductors cannot be formed on a single plane. On the other hand, as illustrated in FIG. 6, for example, one of the linear conductors 1a and 2a is divided at the intersecting position and a pair of terminals 5 is provided there, whereby loop antennas 21a and 21b can be formed on a single plane, the terminals 5 do not interfere with the adjacent loop antenna, and current detection of the target wiring line 50 is not prevented. Note that, in the example of FIG. 6, a case is illustrated where the linear conductor 2a (2b) is divided at the intersecting position.

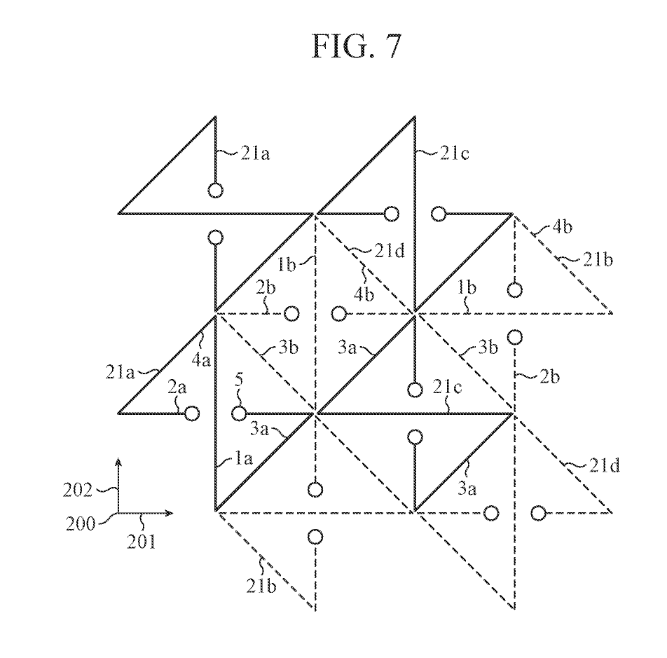

Next, the electromagnetic field probe illustrated in FIG. 7 will be described. In the electromagnetic field probe illustrated in FIG. 7, a plurality of loop antennas (loop antennas 21a and 21c) drawn by solid lines is evenly arranged on a two-dimensional plane, the loop antennas each being at a position of nL in both the X axis 201 and the Y axis 202 from the reference point 200, and the loop antennas 21a and 21c are alternately arranged so that the linear conductors 1a not divided have different orientations. However, similarly to the example illustrated in FIG. 5, n is an integer, and the length of L is set to a value greater than the length of the linear conductor 1a so that the linear conductor 1a is not short-circuited with the conductor of the adjacent loop antenna. In addition, the loop antennas (loop antennas 21b and 21d) indicated by broken lines are inverted left and right with respect to the loop antennas indicated by solid lines, and are arranged each being at a position of nL+L/2 in both the X axis 201 and the Y axis 202 from the reference point 200, and further the loop antennas 21b and 21d are alternately arranged so that the linear conductors 1b not divided have different directions.

As a result, the linear conductors 1a (1b) not divided have different directions alternately, whereby an arrangement can be made not to satisfy conditions where they are aligned to the position and direction of the wiring line 50 for which the magnetic flux is canceled out in the loop of each of the loop antennas.

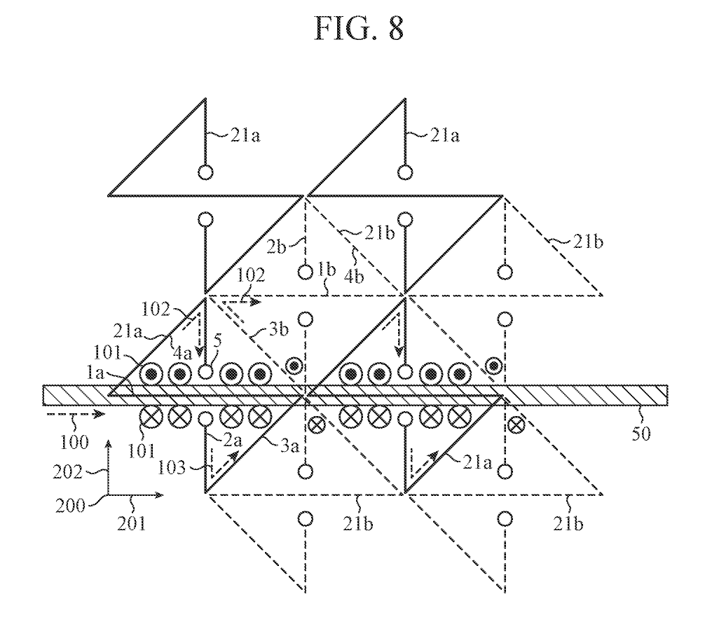

Next, operation of the electromagnetic field probe formed as described above will be described with reference to FIG. 8. In the following, a principle of detecting, by the loop antenna arrangement method illustrated in FIG. 6, a current flowing through the wiring line 50 through which power feeding or signal transmission is performed will be described.

As illustrated in FIG. 8, when a current 100 flows through the wiring line 50 of 0 degrees, clockwise magnetic flux 101 is generated around the wiring line 50 in accordance with the right-handed screw rule. At this time, in the loop antenna 21a, the magnetic flux 101 passes through the upper left loop to the upward direction from the downward direction, and the magnetic flux 101 passes through the lower right loop to the downward direction from the upward direction on the page, whereby an induced current 102 generated in the upper left loop of the loop antenna 21a and an induced current 103 generated in the lower right loop are synthesized in a way in which the induced currents 102 and 103 intensify each other.

As a result, in the case of the electromagnetic field probe illustrated in FIG. 8, the current flowing through the wiring line 50 can be detected. In addition, since the magnetic flux 101 also passes through a loop structure formed by the linear conductors 1b and 2b, and the connecting conductors 3b and 4b, the current flowing through the wiring line 50 can be detected also in the adjacent loop antenna 21b; however, a passing amount of the magnetic flux 101 is greater in the loop antenna on the wiring line 50, and a current detection amount is greater.

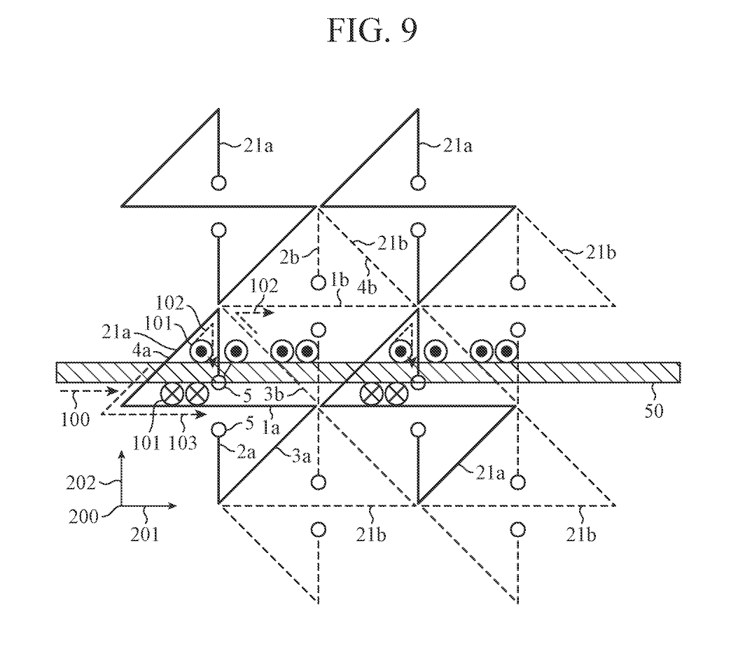

Next, a principle of detecting the current will be described in a case where the wiring line 50 is separated from the center of the loop antenna, with reference to FIG. 9. The wiring line 50 illustrated in FIG. 9 is arranged at a position that halves the area of a loop structure including the linear conductors 1a and 2a, and the connecting conductor 4a. Also in this case, when the current 100 in the direction illustrated flows through the wiring line 50, the clockwise magnetic flux 101 is generated around the wiring line 50 in accordance with the right-handed screw rule. At this time, the upward magnetic flux 101 and the downward magnetic flux 101 equally pass through with the wiring line 50 as the boundary. Therefore, the upward magnetic flux 101 and the downward magnetic flux 101 cancel each other out in the loop, and the induced currents 102 and 103 also cancel each other out.

As a result, in the loop structure including the linear conductors 1a and 2a, and the connecting conductor 4a of the loop antenna 21a illustrated in FIG. 9, the current flowing through the wiring line 50 cannot be detected; however, as for the adjacent loop antenna 21b, the magnetic flux 101 passes through a loop structure including the linear conductors 1b and 2b, and the connecting conductor 3b, so that the current flowing through the wiring line 50 can be detected.

Note that, even when the wiring line 50 rotated clockwise by 90 degrees is arranged, for example, at a position that halves the area of the loop structure including the linear conductors 1a and 2a, and the connecting conductor 4a illustrated in FIG. 9, the current flowing through the wiring line 50 can be detected by the adjacent probe on the same principle.

Note that, in the second embodiment, the reference point 200 is a point at the lower left of a rectangle circumscribing the loop antenna 11a or 21a in the figure; however, the point may be an arbitrary point within a rectangle including the loop antenna. In addition, although the length of L is set to a value greater than the length of the linear conductor 1a, when the lengths of the linear conductor 1a and the linear conductor 2a are different from each other, a value may be set that satisfies L>Ld, where Ld is the length of a longer side among the sides in the X direction and the Y direction including the loop antenna.

As described above, according to the electromagnetic field probe of the second embodiment, a plurality of loop antennas is included on an identical plane, the loop antennas each including: two linear conductors orthogonally arranged to each other without short-circuiting; two connecting conductors connecting both ends of the two linear conductors to each other to form a continuous loop; and a pair of terminals provided at one divided portion in the loop, wherein when Ld is a length of a longer side among sides in an X direction and a Y direction including the loop antenna, L>Ld is set, and n is an integer, the plurality of loop antennas is each arranged to be at a position of nL in both the X direction and the Y direction from a reference point on a two-dimensional plane, and the plurality of loop antennas inverted in the X direction or the Y direction is each arranged to be at a position of nL+L/2 in both the X direction and the Y direction from the reference point, so that a current generated in a wiring line can be detected without changing the orientation of the electromagnetic field probe with respect to wiring lines routed in various directions, and the current can be detected without requiring position control.

In addition, according to the electromagnetic field probe of the second embodiment, the divided portion is provided at an orthogonally intersecting portion of one of the two linear conductors, so that the electromagnetic field probe can be formed on a single plane.

In addition, according to the electromagnetic field probe of the second embodiment, the plurality of loop antennas is arranged so that other linear conductors not divided are oriented in an identical direction, so that a current generated in a wiring line can be detected without changing the orientation of the electromagnetic field probe with respect to wiring lines routed in various directions, and the current can be detected without requiring position control.

In addition, according to the electromagnetic field probe of the second embodiment, the plurality of loop antennas is arranged so that the other linear conductors not divided are oriented differently between the loop antennas adjacent to each other, so that the condition where they are aligned to the position and direction of the measurement target for which the magnetic flux is canceled out in the loop in each of the loop antennas, can be made not to be satisfied, and as a result, there is an effect that orientation control or position control is not necessary, as the electromagnetic field probe.

Note that, in the invention of the present application, within the scope of the invention, free combination of each embodiment, a modification of an arbitrary component of each embodiment, or omission of an arbitrary component in each embodiment is possible.

### INDUSTRIAL APPLICABILITY

As described above, the electromagnetic field probe according to the present invention relates to a configuration using a plurality of loop antennas, and is suitable for detecting a current generated on a printed circuit board wiring line.

### REFERENCE SIGNS LIST

1, 1a, 1b, 2, 2a, 2b: Linear conductor, 3, 3a, 3b, 4, 4a, 4b: Connecting conductor, 5: Terminal, 11, 11a, 11b, 12, 13, 21, 21a, 21b, 21c, 21d, 22, 23: Loop antenna, 50: Wiring line, 100: Current, 101: Magnetic flux, 102, 103: Induced current, 200: Reference point, 201: X axis, 202: Y axis.

1-7. (canceled)

8. An electromagnetic field probe comprising a plurality of loop antennas on an identical plane, the loop antennas each including: two linear conductors orthogonally arranged to each other without short-circuiting; two connecting conductors connecting both ends of one of the two linear conductors to corresponding both ends of another of the two linear conductors to form a continuous loop; and a pair of terminals provided at one divided portion in the loop, wherein
when Ld is a length of a longer side among sides in an X direction and a Y direction including the loop antenna, L>Ld is set, and n is an integer, a first group of the plurality of loop antennas is each arranged to be at a position of nL in both the X direction and the Y direction from a reference point on a two-dimensional plane, and a second group of the plurality of loop antennas inverted in the X direction or the Y direction is each arranged to be at a position of nL+L/2 in both the X direction and the Y direction from the reference point.

9. The electromagnetic field probe according to claim 8, wherein the divided portion is provided at an orthogonally intersecting portion of one of the two linear conductors.

10. The electromagnetic field probe according to claim 9, wherein the plurality of loop antennas is arranged so that other linear conductors not divided are oriented in an identical direction.

11. The electromagnetic field probe according to claim 9, wherein the plurality of loop antennas is arranged so that the other linear conductors not divided are oriented differently between the loop antennas adjacent to each other.
